(19) United States
(12) Patent Application Publication
(10) Pub. No.: US 2008/0309353 A1
(43) Pub. Date: Dec. 18, 2008

(54) CAPACITIVE TOUCH SENSOR

(76) Inventors: MAN KIT JACKY CHEUNG, AUCKLAND (NZ); ADAM JOHNSON, EASTBOURNE (GB)

Correspondence Address: TREXLER, BUSHNELL, GIANGIORGI,;BLACKSTONE & MARR, LTD., 105 WEST ADAMS STREET, SUITE 3600, CHICAGO, IL, 60603, US

(21) Appl. No.: 12/137,234

(22) Filed: Jun. 11, 2008

Related U.S. Application Data
(60) Provisional application No. 60/943,970, filed on Jun. 14, 2007.

(51) Int. Cl. G01R 27/26; H03K 17/955

(52) U.S. Cl. 324/674; 341/33

(57) ABSTRACT

A touch sensor that includes sampling the output of a touch sensor circuit supplied with a high level carrier signal at least once, sampling the output of a touch sensor circuit supplied with a low level carrier signal at least once and thereby determining the occurrence of a touch by using at least one of said high level carrier samples and at least one of said low level carrier samples.

### FIELD OF THE INVENTION

The present invention relates to touch sensors, in particular to touch sensor methods and circuits for overcoming noise induced in a capacitive divider touch sensor circuit.

### BACKGROUND OF THE INVENTION

A capacitive touch sensor circuit can be built from an oscillator circuit that generates a varying signal and connects to a capacitive divider circuit. A receiver circuit is arranged to measure the output of the capacitive divider. The capacitive divider circuit incorporates a touch pad that a person may interact with using their body or indirectly via a plunger or actuator. The capacitance across a touch pad varies when the touch pad surface is touched. Accordingly, the capacitive divider ratio changes causing a change in signal amplitude input to the receiver circuit changes. A touch can be detected when the oscillator signal level drops below a predetermined threshold.

In an electrically or electromagnetically noisy environment, a person induces noise to the touch sensor circuit through their body. The induced noise can mask the drop in oscillator signal level, thus causing difficulty detecting whether a touch has occurred.

### SUMMARY OF THE INVENTION

It is therefore an object of the present invention to provide touch sensing methods or circuits that go some way toward overcoming the effect of noise induced in a capacitive touch sensor circuit, or at least to provide the public with a useful choice.

In a first aspect the invention is said to consist in a method of sensing the occurrence of a touch comprising:
sampling the output of a touch sensor circuit supplied with a high level carrier signal at least once,
sampling the output of a touch sensor circuit supplied with a low level carrier signal at least once,
determining the occurrence of a touch by using at least one of said high level carrier samples and at least one of said low level carrier samples.

Preferably said touch sensor circuit supplied with said high level carrier sample and said touch sensor circuit supplied with said low level carrier signal are ultimately the same circuits.

Preferably said high level carrier signal and said low level carrier sample are ultimately the same signal.

In another aspect the invention is said to consist in a method of sensing the occurrence of a touch comprising:
generating a modulated signal,
applying said modulated signal to the input of a touch sensor,
sampling the output of said touch sensor during a first (high) portion in the modulated signal to obtain one or more samples of said output during said high portion,
sampling the output of said touch sensor during a second (low) portion in the modulated signal to obtain one or more samples of said output during said low portion,
determining the occurrence of a touch by using at least one of said high samples and at least one of said low samples.

Preferably said modulated signal comprises a modulation signal modulating a carrier signal.

Preferably determining the occurrence of a touch includes comparing a difference between said first and said second samples against a threshold.

Preferably said threshold is between 50 and 97% of a historical average or difference between said first and said second samples.

Preferably said difference is calculated from a recent historical set of said first and said second samples.

Preferably said first sample comprises said carrier signal and said second sample comprises noise.

Preferably said modulation signal is a square wave that switches the amplitude of said carrier signal high and low thus having a digitally resolvable voltage differential.

Preferably said digitally resolvable voltage differential is at least thirty ADC counts.

Preferably said carrier signal is between 100 kilohertz and 1 megahertz.

Preferably said modulation signal is between 50 hertz and 1 kilohertz.

Preferably the occurrence of a touch is sensed by:
applying a first digital filter, and a second digital filter to a signal representing the difference between said high samples and said low samples; and determining a touch has occurred when the output of said first filter is below the output of said second filter.

Preferably at least one of said first digital filter and said second digital filter are a moving window filter.

Preferably at least one of said first digital filter and said second digital filter are a forgetting factor filter.

Preferably the sampling instance is synchronised with the frequency of said carrier signal.

In another aspect the invention is said to consist in a sensor device, comprising:
a touch sensor for switching a circuit,
a waveform generator for generating a modulated signal including alternating high and low voltage regions,
a sampler adapted to repeatedly sample high regions and low regions of said modulated signal and provide first portion data relating to said high region and second portion data relating to said low region, and
a processor programmed to determine the occurrence of a touch from said first and second portion data.

Preferably said touch sensor is a capacitive touch pad.

Preferably said waveform generator is a processor adapted to generate signals.

Preferably said sampler is a processor adapted to perform analogue to digital conversions.

Preferably said processor is a computation device adapted to manipulate sampled signals.

Preferably said processor is adapted to include said waveform generator, said sampler and a computation device adapted to manipulate sampled signals.

Preferably the occurrence of a touch is sensed by:
subtracting said second portion data from said first portion data to produce third portion data,
applying a first digital filter, and a second digital filter to said third portion data; and
determining a touch has occurred when said first filter output is below the level of said second filter output.

A sensor device as claimed in claim 24, wherein at least one of said first digital filter and said second digital filter is a moving window filter.

Preferably at least one of said first digital filter and said second digital filter is a forgetting factor filter.

Preferably said modulated signal comprises a modulation signal modulating a carrier signal.

Preferably said carrier signal has a frequency between 100 kilohertz and 1 megahertz.

Preferably said modulation signal has a frequency between 50 hertz and 1 kilohertz.

Preferably said touch sensor device comprises:
a touch sensor circuit,
a signal generator for generating a modulated signal including a carrier signal modulated by a modulation signal,
a sampler adapted to sample said modulated signal, and
a processor adapted to determine the occurrence of a touch wherein said carrier signal is at least twice the frequency of said modulation signal.

Preferably said touch sensor is a capacitive touch pad.

Preferably said signal generator is a processor adapted to generate signals.

Preferably said sampler is a processor adapted to perform analog to digital conversions.

Preferably said processor is a computation device.

Preferably said processor is adapted to include said signal generator, said sampler and a computation device adapted to manipulate sampled signals.

To those skilled in the art to which the invention relates, many changes in construction and widely differing embodiments and applications of the invention will suggest themselves without departing from the scope of the invention as defined in the appended claims. The disclosures and the descriptions herein are purely illustrative and are not intended to be in any sense limiting.

### BRIEF DESCRIPTION OF THE DRAWINGS

A preferred embodiment will be described with reference to the figures.

FIG. 1 is a block diagram illustrating an arrangement of system components.

FIG. 2 is a block diagram illustrating an arrangement of sub circuits in the touch sensor circuit.

FIG. 3 is a schematic drawing of the touch sensor circuit when the touch sensor is not being touched.

FIG. 4 is a schematic drawing of the touch sensor circuit when the touch sensor is being touched.

FIGS. 5a and 5b illustrate examples of touch sensor pad configurations.

FIG. 6 illustrates a signal suitable for use as a modulation signal.

FIG. 7 illustrates a carrier signal when is has been modulated by a modulation signal.

FIG. 8 shows a sample of the signal at the output of the touch sensor circuit during a touch.

FIG. 9 illustrates the signal at the output of the touch sensor circuit when noise has been induced onto the signal during a touch.

FIG. 10 illustrates the noise induced during a touch at the output of the touch sensor circuit with no signal present.

### DETAILED DESCRIPTION

The present invention relates to a method of overcoming noise induced by a persons touch to a capacitive divider touch sensor circuit.

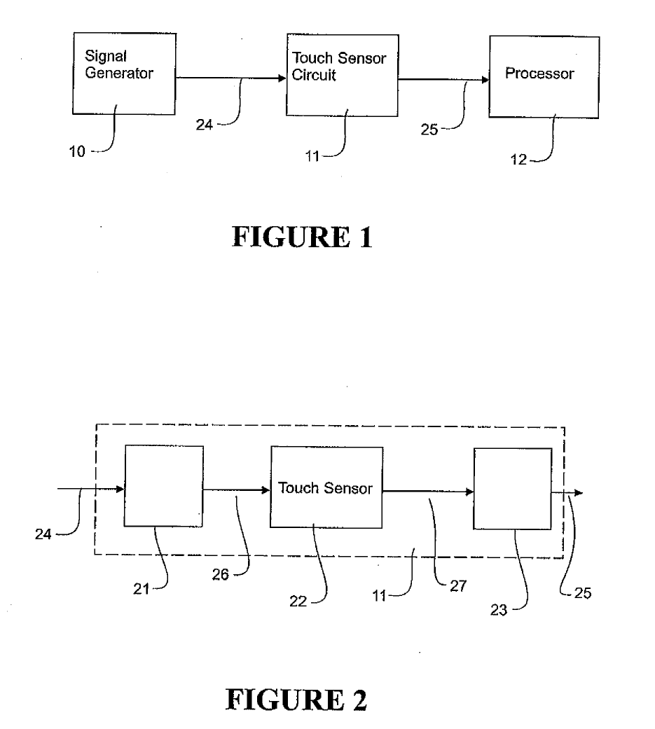

FIG. 1 illustrates an overview of the touch sensor circuit arrangement. The circuit is constructed from several functional building blocks. A signal generator 10 produces desired carrier waveforms at frequencies applicable to a touch sensor system. The signal generator 10 may be analogue or digital, a discrete circuit or an output of a microprocessor. Alternatively the signal generator 10 may be built from discrete analogue components and tuned to generate desired waveform at desired frequencies.

The signal produced by the generator 10 is supplied to a touch sensor divider circuit 11 through a generic conductor 24. The output 25 of the touch sensor circuit is connected to an analogue to digital converter (ADC) and processor 12. The ADC digitises the signal output 25 from the touch sensor circuit 11. The digitised signal output is analysed by the processor 12 according to an algorithm used to determine the occurrence of a touch.

Preferably the signal generator 10, ADC and processor 12 ate incorporated within a single microprocessor. Alternatively, only the ADC and processor could be incorporated within a single microprocessor. Alternatively still, the ADC and processor could be separate or stand alone units. In a preferred embodiment of the invention a single microprocessor generates the desired waveforms and outputs them to the touch sensor circuit 11, the output of the touch sensor circuit 11 returns to an ADC input on the same microprocessor.

An embodiment of the preferred touch sensor divider circuit 11 includes three sub circuits. The arrangement of the three sub circuits is shown in FIG. 2. The first sub circuit may generally be referred to as a transmitter circuit 21. The second sub circuit is a capacitive divider 22. The third sub circuit may generally be referred to as a receiver circuit 23. The transmitter circuit 21 receives an input signal 64 that is generated by the signal source 10. The transmitter circuit 21 buffets the input signal 64 and amplifies it. In an alternative embodiment of the invention the transmitter circuit is omitted if the signal generator 10 produces sufficient signal power to drive the capacitive divider directly.

The preferred capacitive divider circuit 22 is formed from two capacitors. A first capacitor 30 is a touch pad. The capacitor 30 is designed by a circuit engineer to form the touch pad from adjacent metal track on a circuit board. Alternatively the capacitor can be formed on the surface of a control panel or user interface.

A variety of physical inplementations of the pad capacitor for touch sensor are known in the art. For example, a typical characteristic of the capacitor touch pad is a network of two conductors that interleave without connecting together.

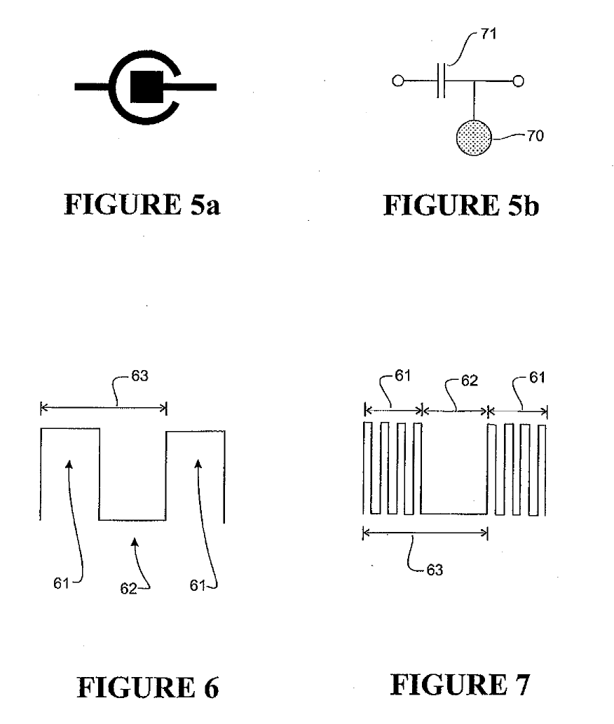

FIG. 5a illustrates a touch pad that has been etched into a printed circuit board track. The configuration and surface area of the track determines the value of the capacitor. FIG. 5b illustrates an alternative touch pad configuration arranged from a discrete capacitor 70 and a touch surface 71. The touch surface 71 may comprise a conductive layer disposed beneath the surface of a screen or translucent panel.

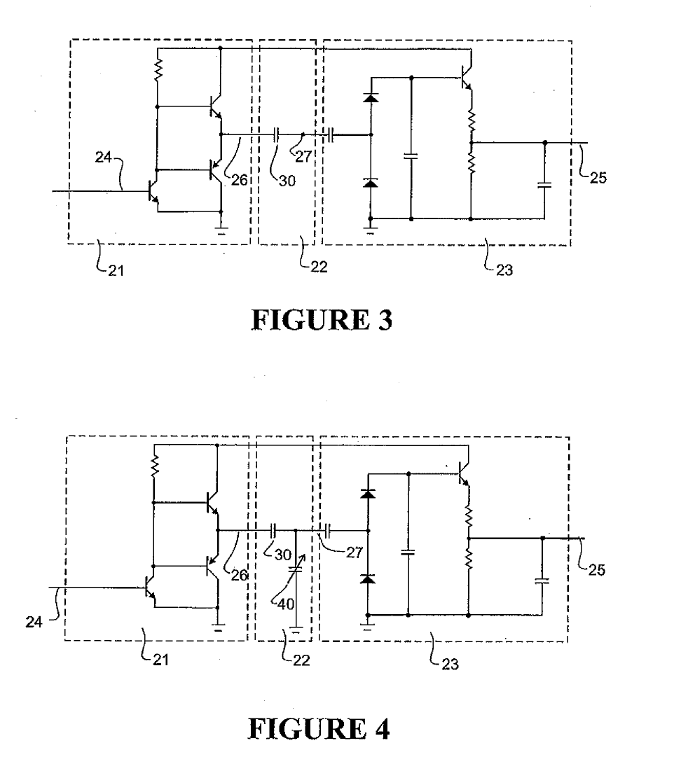

FIG. 3 illustrates the touch sensor circuit 11 in the condition when the touch pad capacitor 30 is untouched. A substantial portion of the oscillating signal supplied on conductor 26 to touch pad capacitor 30 will be coupled across to the receiver circuit 23 via conductor 27.

The touch pad is typically arranged so that a person may directly interact with the touch pad capacitor 30 using their finger. Alternatively a person may actuate a plunger or lever with a striking surface that interacts with the touch pad.

A person placing their finger on the surface of the touch pad 30 effectively changes the capacitance value of the touch pad capacitor 30. This is due to the human body having natural impedance that couples electrical energy away from the touch sensor circuit. The change in capacitance is used to determine when a “touch” has occurred. FIG. 4 illustrates the touch sensor circuit 11 as having an extra coupling capacitance when a person is touching the touch pad 30.

During the occurrence of a touch a capacitive voltage divider is effectively formed. The divider 22 reduces the amplitude of the oscillating signal that reaches the receiver sub-circuit 23. The receiver sub-circuit 23 buffers the output of the capacitive divider 22 to condition the signal and isolate the effects of devices connected to the receiver 23 output from influencing the capacitive divider.

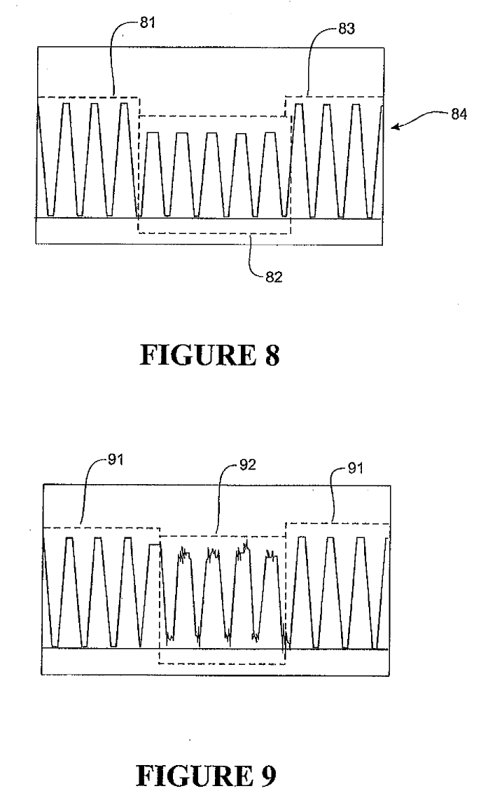

FIG. 8 illustrates a typical output from the touch sensor circuit The signal shows a steady amplitude portion 81, followed by a reduction in amplitude portion 82. Portion 82 of the signal indicates that electrical energy is being coupled away from the touch pad capacitor 30. The drop in signal amplitude is therefore used to determine whether a touch has occurred. For example, a touch is confirmed when the maximum amplitude of the digitised waveform drops below a threshold determined from recent historic amplitudes of the waveform.

Noise can be induced into the touch sensor circuit by a human touch. This is because the human body will naturally conduct electrical noise from the environment. Noise is commonly introduced into a touch sensor circuit when the person operating the touch switch is in an electrically or electromagnetically charged environment, such as in the vicinity of electric motors ort radio transmitters.

FIG. 9 illustrates a typical output from the touch sensor circuit 11 when noise is induced by the user during the period when their finger contacts the touch pad 30. The addition of noise to signal portion 92 partially cancels or masks the amplitude drop associated with a touch. The noise source is decoupled from the circuit and the signal returns to normal when the user lifts their finger from the touch pad surface, for example, at signal portion 91. The partial cancellation effect the addition of noise creates can cause the maximum amplitude of the signal to remain above the threshold 84 required to detect a touch has occurred.

In the preferred embodiment of the invention the signal generator 10 produces two waveforms. The first waveform is a carrier signal The second waveform is a modulation signal. Preferably each of the carrier and modulation signals is a square wave.

The inventors have ascertained the most practical frequency range for the carrier signal is between 100 KHz and 1 MHz. Similarly, the inventors have ascertained the most practical frequency range for the modulation signal is between 50 Hz and 1 KHz.

The low frequency modulation signal modulates the carrier signal. For example, the signals may be fed to inputs of an AND logic gate. The effect of the modulation is to switch the carrier signal high and low depending on whether the modulation signal is high or low respectively.

The microprocessor could be used to be used to generate the carrier signal and switch it on and off without the need to generate the modulation signal. The microprocessor could also generate the carrier and modulation signal and sum them internally, or externally through an AND logic gate. Alternatively, the carrier signal, or modulation signal, or both, could be generated by a discrete signal generator of any known type including analogue, digital or hybrid implementations. The discrete signal generator could be controlled by microprocessor.

FIG. 6 illustrates an example of the modulation signal. Preferably the modulation signal is a square wave having a period 63. The “high” state of the modulation signal 61 corresponds the where the carrier signal is switched on at the output of the signal generator. The “low” state of the modulation signal 62 indicates where the carrier signal is switched off at the output of the signal generator.

FIG. 7 illustrates an example of the modulated signal that can be observed at the output of the preferred signal generator. The high state voltage need not be the maximum voltage available in the circuit. Similarly the low state voltage need not be the minimum voltage available in the circuit. However, an adequate voltage differential between the high and low states is advantageous for digital sampling purposes. An ADC having a particular bit depth has a particular voltage resolution associated with that bit depth. A voltage differential of thirty ADC counts is usually adequate to resolve a high state from a low state.

The modulated signal output to the touch sensor circuit is sampled by an ADC at the output of the circuit. Preferably, the ADC is incorporated as part of the microprocessor. The modulated signal is sampled when in the high state 61. The modulated signal is then sampled when in the low state 62. The modulated signal may be sampled continuously by the ADC and the relevant portions processed by the software of the microprocessor.

It is preferable to synchronise the sampling timing with the particular carrier frequency used. The periods between when each sample is taken ate not necessarily equal. Unequal sampling periods may be used to allow for unequal periods of rising and falling edge where the carrier signal is influenced by inherent electrical properties of the circuit. Unequal rise and fall times may arise, for example, when a capacitor takes longer to charge than to discharge.

In the preferred embodiment, a single sample is taken when the carrier is in the high state at the peak of the carrier waveform. Alternatively, a sample representing the peak of the carrier signal could be used. For example, a series of samples could be taken when the carrier signal is in the high state. The series of samples could then be, for example, averaged, or the peak value taken, or the RMS value taken to represent the carrier signal sample.

Any noise in the touch sensor circuit 11 will be substantially isolated at the output of the circuit 25 when the modulated signal is in the low state. Similarly when the modulated signal is in high state 62, the signal at the output of the touch sensor circuit will include any additional noise.

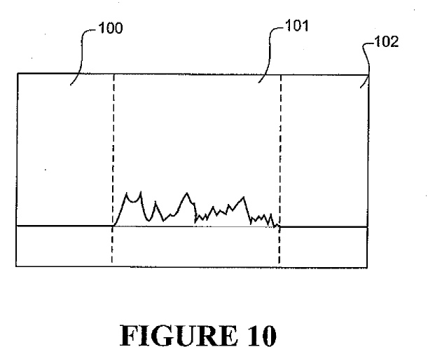

FIG. 10 illustrates a typical output signal from the touch sensor circuit where the carrier signal is in the low state and a touch has occurred during signal portion 101. The user induces noise from the environment into the touch sensor circuit. The signal remains noise free when the touch sensor is not in contact with the user 100, 102.

Preferably a third sample is created by subtracting the second sample from the first sample. The third sample will be referred to as the effective output sample Vout. The second sample taken when the modulation signal is in the low state effectively therefore represents the noise level induced by a touch. The third sample is therefore designed to closely represent the signal that would be output from the circuit if there was no noise present.

The sampling process can be summarised according to the following steps.
1. The signal output from the touch sensor circuit is sampled when the modulated signal is in the high state to create first sample Vmax.
2. The signal output from the touch sensor circuit is sampled when the modulated signal is in the low state to create second sample Vmin.
3. An effective output sample Vout results from subtracting the second sample from the first sample: Vmax−Vmin=Vout.

The effective output sample Vout created by the subtraction of the two samples is passed through two digital filters. The digital filters process each of the Vout samples by calculating a moving average. A moving average is typically calculated as the average value of a certain quantity of sampled voltages. Alternatively the moving average filter is replaced with filter based on a forgetting factor calculation. Preferably each filter has a response time governed by the quantity of samples they give weight to,

Additional filtering techniques may include weighting a selection of the samples to influence the result of calculation more than samples that have not been weighted. For example, a forgetting function weights recent values higher than older values.

For example, in a forgetting function embodiment of the filter, the Kth effective signal output Vout sample, Vk, is passed through two digital filters. Yk can be considered a ‘slow’ filter, and Zk a ‘fast’ filter. For example:

Yk=mVk+(1−m)Yk−1 1.

Zk=nVk+(1−n)Zk−1 2.

where m<n<1.

In another example, in a moving window embodiment of the filter:

Yk=mkVk+mk−1Vk−1+. . . mk−iVk−i 1.

Zk=nkVk+nk−1Vk−1+. . . nk−iVk−i 2.

Where i is a constant and n can be any number greater than, or equal to zero.

The quantity of samples the filter processes or the rate of which older values teach negligible weighting determines the time constant for that filter. For example, a single sample might be processed for a filter having a short time constant, while four or more samples might be processed when the filter has a long time constant. The time constant of the filter affects the reliability and response time of the system. A short time constant may be compensated by requiring a longer time for the filter output to be below the touch triggering threshold to avoid false triggering. Additionally, the time constant must not be too long or the response time of the touch sensor system will be slow. A slow response may also lead to the sensor missing a quick touch. As a result, the inventors have ascertained that the time constant for each filter should be in the range of 1 ms to 100 ms.

The output from the slow filter, Yk, is used as a reference level. In the preferred implementation the touch threshold at any given time, Tk, is given by

Tk=C×Yk, where constant C<1.

The inventors have ascertained that typical values for constant C would be between 50% and 97%. Tk represents a signal level below the recent average high carrier level after subtraction of the noise signal, and therefore a touch threshold. A touch is determined by the output from the fast filter Zk dropping below the touch threshold Tk for more than a predetermined number of consecutive samples.

The microprocessor may generate a flag or an interrupt when a touch is detected. The flag or interrupt may be used to activate subsequent blocks of software code that process other functions built into the microprocessor. Alternatively the flag or interrupt may be used to switch an output pin on the microprocessor. The pin may be connected to an external device that, for example, operates another independent system or device in response to a switched input.

It is possible to implement the functions of the microprocessor using other means. For example, the functions of the microprocessor could be implemented with discrete logic elements or analogue components. However, the performance or flexibility of a system implemented in such other ways is reduced.

One example of a way to implement the desired system using analogue components includes the use of operational amplifiers to perform real-time waveform subtraction of the signals obtained during the high and low states of the modulated signal.

Analogue filters could be used to replace digital filtering techniques described in the preferred embodiment. However such analogue systems would requite tuning for the particular environment they were to operate in, thus providing an inelegant solution to the problems associated with overcoming noise in a touch sensor circuit.

1. A method of sensing the occurrence of a touch comprising:
sampling the output of a touch sensor circuit supplied with a high level carrier signal at least once,
sampling the output of a touch sensor circuit supplied with a low level carrier signal at least once,
determining the occurrence of a touch by using at least one of said high level carrier samples and at least one of said low level carrier samples.

2. A method of sensing the occurrence of a touch as claimed in claim 1, wherein said touch sensor circuit supplied with said high level carrier sample and said touch sensor circuit supplied with said low level carrier signal are ultimately the same circuits.

3. A method of sensing the occurrence of a touch as claimed in claim 1, wherein said high level carrier signal and said low level carrier sample are ultimately the same signal.

4. A method of sensing the occurrence of a touch comprising:
generating a modulated signal,
applying said modulated signal to the input of a touch sensor,
sampling the output of said touch sensor during a first (high) portion in the modulated signal to obtain one or more samples of said output during said high portion,
sampling the output of said touch sensor during a second (low) portion in the modulated signal to obtain one or more samples of said output during said low portion,
determining the occurrence of a touch by using at least one of said high samples and at least one of said low samples.

5. The method of sensing the occurrence of a touch as claimed in claim 4, wherein said modulated signal comprises a modulation signal modulating a carrier signal.

6. The method of sensing the occurrence of a touch as claimed in claim 4, wherein determining the occurrence of a touch includes comparing a difference between said first and said second samples against a threshold.

7. The method of sensing the occurrence of a touch as claimed in claim 6, wherein said threshold is between 50 and 97% of a historical average or difference between said first and said second samples.

8. The method of sensing the occurrence of a touch as claimed in claim 5, wherein said difference is calculated from a recent historical set of said first and said second samples.

9. The method of sensing the occurrence of a touch as claimed in claim 5, wherein said first sample comprises said carrier signal and said second sample comprises noise.

10. The method of sensing the occurrence of a touch as claimed in claim 5, wherein said modulation signal is a square wave that switches the amplitude of said carrier signal high and low thus having a digitally resolvable voltage differential.

11. The method of sensing the occurrence of a touch as claimed in claim 10, wherein said digitally resolvable voltage differential is at least thirty ADC counts.

12. The method of sensing the occurrence of a touch as claimed in claim 5, wherein said carrier signal is between 100 kilohertz and 1 megahertz.

13. The method of sensing the occurrence of a touch as claimed in claim 5, wherein said modulation signal is between 50 hertz and 1 kilohertz.

14. The method of sensing the occurrence of a touch as claimed in claim 4, wherein the occurrence of a touch is sensed by:
applying a first digital filter, and a second digital filter to a signal representing the difference between said high samples and said low samples; and determining a touch has occurred when the output of said first filter is below the output of said second filter.

15. The method of sensing the occurrence of a touch as claimed in claim 14, wherein at least one of said first digital filter and said second digital filter are a moving window filter.

16. The method of sensing the occurrence of a touch as claimed in 14, wherein at least one of said first digital filter and said second digital filter ate a forgetting factor filter.

17. The method of sensing the occurrence of a touch as claimed in claim 4, wherein the sampling instance is synchronised with the frequency of said carrier signal.

18. A sensor device, comprising:
a touch sensor for switching a circuit,
a waveform generator for generating a modulated signal including alternating high and low voltage regions,
a sampler adapted to repeatedly sample high regions and low regions of said modulated signal and provide first portion data relating to said high region and second portion data relating to said low region, and
a processor programmed to determine the occurrence of a touch from said first and second portion data.

19. A sensor device as claimed in claim 18, wherein said touch sensor is a capacitive touch pad.

20. A sensor device as claimed in claim 18, wherein said waveform generator is a processor adapted to generate signals.

21. A sensor device as claimed in claim 18, wherein said sampler is a processor adapted to perform analogue to digital conversions.

22. A sensor device as claimed in claim 18, wherein said processor is a computation device adapted to manipulate sampled signals.

23. A sensor device as claimed in claim 18, wherein said processor is adapted to include said waveform generator, said sampler and a computation device adapted to manipulate sampled signals.

24. A sensor device as claimed in claim 18, wherein the occurrence of a touch is sensed by:
subtracting said second portion data from said first portion data to produce third portion data,
applying a first digital filter, and a second digital filter to said third portion data; and determining a touch has occurred when said first filter output is below the level of said second filter output.

25. A sensor device as claimed in claim 24, wherein at least one of said first digital filter and said second digital filter is a moving window filter.

26. A sensor device as claimed in 24, wherein at least one of said first digital filter and said second digital filter is a forgetting factor filter.

27. The method of sensing the occurrence of a touch as claimed in claim 18, wherein said modulated signal comprises a modulation signal modulating a carrier signal.

28. A sensor device as claimed in claim 27, wherein said carrier signal has a frequency between 100 kilohertz and 1 megahertz.

29. A sensor device as claimed in claim 27, wherein said modulation signal has a frequency between 50 hertz and 1 kilohertz.

30. An appliance including a touch sensor device, wherein said touch sensor device comprises:
a touch sensor circuit,
a signal generator for generating a modulated signal including a carrier signal modulated by a modulation signal,
a sampler adapted to sample said modulated signal, and
a processor adapted to determine the occurrence of a touch wherein said carrier signal is at least twice the frequency of said modulation signal.

31. An appliance as claimed in claim 30, wherein said touch sensor is a capacitive touch pad.

32. An appliance as claimed in claim 30, wherein said signal generator is a processor adapted to generate signals.

33. An appliance as claimed in claim 30, wherein said sampler is a processor adapted to perform analog to digital conversions.

34. An appliance as claimed in claim 30, wherein said processor is a computation device.

35. An appliance as claimed in claim 30, wherein said processor is adapted to include said signal generator, said sampler and a computation device adapted to manipulate sampled signals.
